(19) United States
(12) Patent Application Publication
(10) Pub. No.: US 2004/0250994 A1
(43) Pub. Date: Dec. 16, 2004

(54) Methods and apparatuses for electronics cooling

(76) Inventor: Lalit Chordia, Pittsburgh, PA (US)

Correspondence Address: Lalit Chordia, Thar Technologies, Inc., 730 William Pitt Way, Pittsburgh, PA, 15238, US

(21) Appl. No.: 10/702,396

(22) Filed: Nov. 5, 2003

Related U.S. Application Data
(60) Provisional application No. 60/424,142, filed on Nov. 5, 2002.

(51) Int. Cl. H05K 7/20

(52) U.S. Cl. 165/80.4; 361/699; 165/104.33

(57) ABSTRACT

Methods and apparatuses for cooling a device are disclosed. The device may be an electrical or electronic component that includes an integrated circuit or embedded control. The apparatus employs a fluid that near or above its critical pressure and at least one heat exchanger. At least two configurations are disclosed: one with a pump and another without a pump.

### CROSS-REFERENCE TO RELATED APPLICATION:

This application claims priority to U.S. Provisional patent application Ser. No. 60/424,142 filed Nov. 5, 2002, which is incorporated herein by reference.

### BACKGROUND

1. Field

Aspects of this disclosure generally relate to cooling devices and methods that employ a fluid near or above its critical pressure, and more particularly to a small-scale apparatus needed to operate such a cycle. Typical target applications include, for example, cooling of computers, computer components, analytical and laboratory equipment, lasers, and remote sensing equipment.

2. Background

The cooling of such devices as computers, servers, telecommunications switchgear and numerous other types of electronic equipment and medical equipment has been an intense area of research for quite some time. Until recently, these types of equipment have been cooled by such simple devices as fans and non-mechanical heat spreaders. The need for increased performance of such devices, together with ever increasing compactness, has led to greatly increased levels of heat dissipation from these devices, with the consequence that the conventional forms of cooling are in many cases unable to prevent device temperatures from rising too high, causing the devices to fail. Furthermore, some device designers do not merely want to prevent harmful temperature rises but also to facilitate performance-enhancing temperature decreases. For example, electronic equipment can run faster and can be more reliable if cooled sufficiently. Thus, a need exists for small-scale equipment that can cool devices to safe operating temperatures and that enhance performance.

Much effort has been devoted to improving the cooling of electronic components with forced air. Because space and cost considerations limit the size of fans that can be employed, greater attention is devoted to the heat sink that withdraws heat from a hot component by conduction, whereupon a fan cools it by forced convection. Another method of improving the heat sink is to construct it as a thermoelectric cooler, known as a Peltier cooler, which enables the temperature of the heat sink at the junction with the heat source to be substantially below the temperature of the heat source. Peltier coolers require more input power than can be dissipated and are therefore an inefficient means of microrefrigeration.

The attachment of a heat pipe to an electronic component is another method of removing heat from a target device. Typically, in a heat pipe, one end is exposed to the heat source while the other end is exposed to the heat sink. The heat sink is always at a lower temperature than the heat source. Evaporation of a liquid phase working fluid to a vapor inside the heat pipe at the exposed end allows for heat to be absorbed from the heat source. The vapor phase working fluid, containing the absorbed heat load, is driven to the opposite end of the heat pipe thermodynamically due to a pressure difference created between the heat sink and heat source.

The working fluid then rejects the heat load to the heat sink and subsequently condenses back to a liquid at the heat sink end of the heat pipe. The liquid phase working fluid then travels back through the heat pipe to the heat source end and the process is repeated. Bhatia (U.S. Pat. No. 6,209,626) describes a heat pipe for use in a cooling device that has internal capillary flow. Ishida et al. (U.S. Pat. No. 6,408,934) describe a cooling module comprised of a collector for receiving heat, a fan motor, blades and a fin structure, and a heat pipe.

While heat pipes have been garnering much attention in the research, one embodiment of the present invention discloses an alternative to heat pipe technology by using a heat rejector, heat acceptor and a pump with a fluid above its critical pressure. In another embodiment, the fluid moves by means of thermal siphoning in which case, density differences that result from temperature changes are exploited to cause the fluid to move in the loop. Near the critical pressure, small temperature differences result in large density differences which result in stronger driving forces for mass flow. A further benefit near the critical pressure is the low viscosity of the fluid which results in low resistance to flow.

Objects

An object of this disclosure is to provide novel methods and apparatuses for the cooling of a device. The apparatus provides a means of cooling target devices including electrical or electronic components having at least an integrated circuit or embedded control.

Another object of the present disclosure is to assemble the cooling device in an integrated package that can be incorporated within electronic or other small-scale appliances or to distribute the components across the elements and packaging of the items being cooled.

Another object of the present disclosure is to derive power to operate the cooling apparatus from the same public power source that drives the electronic or other small-scale appliance, without requiring more power than that which is dissipated in the process of refrigeration or from an independent source.

Another object of this disclosure is to provide a method and apparatus for electronics cooling with or without the use of a pump.

Yet another object of this disclosure is to achieve the aforementioned goals using a fluid near or above its critical pressure.

### SUMMARY

An apparatus for cooling a device includes the following components: a fluid that is near or above its critical pressure, a heat exchanger, a pump for circulating the fluid, and a fluid connection between the heat exchanger and the pump. The device may be an electrical or electronic component that includes an integrated circuit or embedded control. The fluid may be carbon dioxide, water, air, or natural hydrocarbon. The pump may utilize electrical, electromechanical, mechanical, or magnetic means of fluid flow and the actuation of the pump may be electrohydrodynamic, electroosmotic, magnetic, or electromechanical actuation. The heat exchanger is of microchannel type.

The disclosure further relates to the apparatus recited above, where an absence of lubricants increases the performance of the apparatus. Control may be provided by software, hardware, or other method. A sensor may be used to monitor and control temperature and temperature-related phenomena. Power may be derived from a public power network of the device or an independent source.

The disclosure further relates to the apparatus recited above, where the heat exchanger and the pump are contained in the apparatus package. A heat exchanger may be external to the apparatus package. The external heat exchanger is connected to the apparatus by a fluidic connection. The heat exchanger is integrated into a package of the device. The external heat exchanger is in thermal contact with the device.

Further aspects of the apparatus as recited include the fluid comprising thermally conductive nanoparticles to increase cooling performance and an additional effect of electrohydrodynamic, electroosmotic, or magnetic effect may be used to increase cooling performance.

An apparatus for cooling a device includes the following components: a fluid that is near or above its critical pressure, two heat exchangers and a fluid connection between the heat exchangers. The details of the disclosure mentioned in the previous paragraphs can also be applied to this apparatus as well. In addition, the apparatus provides for a density difference to be maintained between the heat exchangers. Additionally, nanomaterials with high heat capacity may be added to the fluid to reduce the flow rate. Alternatively, the fluid may be a highly conducting fluid.

A method for cooling a device that consists of the following: providing a fluid near or above its critical pressure, transferring heat from the device to the fluid, transferring heat from the fluid to an external environment, and providing a pump for fluid flow. The details of the disclosure mentioned in the previous paragraphs can also be applied to this method as well.

A method for cooling a device that consists of the following: providing a fluid near or above its critical pressure, transferring heat from the device to the fluid and transferring heat from the fluid to an external environment. The details of the disclosure mentioned in the previous paragraphs can also be applied to this method as well.

### BRIEF DESCRIPTION OF THE DRAWINGS

The drawings are provided to illustrate some of the embodiments of the disclosure. It is envisioned that alternate configurations of the embodiments of the present disclosure maybe adopted without deviating from the disclosure as illustrated in these drawings.

A detailed description of the disclosure follows with reference to the following drawings:

FIG. 1 is a schematic representation of the microcooler for electronics cooling that utilizes a pump.

FIG. 2 is a schematic representation of the microcooler for electronics cooling that does not utilize a pump.

### DETAILED DESCRIPTION

### Definitions

“Cooling” means

Removing heat

“Condenser” means

A heat exchanger for transferring heat from the fluid to an environment outside the closed loop

“Evaporator” means

A heat exchanger for transferring heat from a device to the fluid of the closed loop

“Microchannel” means

A pathway having a dimension about 3,000 micrometers or less

“Device” means

An electrical, electronic, or optical element within an appliance or the appliance itself with at least an integrated circuit or embedded control that generates heat, including but not limited to, computing equipment, radio frequency devices, telecommunications switchgear, military hardware, laser devices, infrared devices, and numerous other types of electronic equipment, medical equipment, and many more items that are generally compact in design

“Nanoparticles” means

Particles below one micrometer in size

“Actuation” means

To initiate motion

“Electroosmotic” means

Moving a fluid using an electric field and the osmosis concept

“Electrohydrodynamic” means

Inducing fluid flow in a dielectric medium by means of high voltage and tow electric current.

“Electromechanical” means

A mechanical process or device actuated or controlled electronically

“High thermal conducting fluid” means

a fluid having thermal conductivity higher than 25 watt/m K.

Description

The present disclosure provides novel methods and apparatuses for cooling using a fluid near or above its critical pressure. The cooling methods herein relate to a sealed, closed loop for circulation of a fluid. The cooling system is comprised of at least one heat exchanger and may include a pump. All components may be connected within a closed circuit and may be integrated into one package or distributed throughout the device. The apparatus provides a means of cooling devices, including, but not limited to, electrical and electronic devices, and other devices and components having at least an integrated circuit or embedded control. Examples of such devices include electrical, electronic or optical elements within an appliance or the appliance itself, with at least an integrated circuit or embedded control that generates heat, including computers, servers, telecommunications switchgear, radio frequency devices, lasers and numerous other types of electronic equipment, medical equipment, military hardware and many more items that are generally compact in design.

In its basic operation, the apparatus causes a cooling fluid to circulate between a heat acceptor, where heat is absorbed from the device being cooled, and a heat rejecter, where the absorbed heat is discharged from the apparatus, thereby cooling the fluid so that it can re-circulate to the heat accepter. The fluid flows through small channels of less than 1 millimeter in length, width or diameter. Because of frictional forces within these channels, the fluid must be impelled in some manner. The present disclosure describes two methods of impelling the fluid—one by means of a pump, the other by utilizing density differences and thereby doing without a pump. The heat rejecter in this apparatus is a type of heat exchanger that causes heat from the apparatus' fluid to transfer to an ambient fluid, typically air. The heat accepter in this apparatus is a heat exchanger than is in direct or indirect contact with the device.

According to the present disclosure, a pump may be used in the system to circulate a fluid around the closed circuit and through at least one or more heat exchangers for accepting and rejecting heat. The pump may be used for circulation of the fluid through the loop. Many types of pumps can be used for the purpose. The pump can be electrical in nature, meaning that the driving force is strictly electrical in nature and does not involve mechanical moving parts. Specific examples of electrical pumps include electrohydrodynamic (EHD) and electroosmotic (EO) pumps. In EHD pumps, an electric field is applied to a dielectric fluid, inducing an electric charge in the fluid and dragging fluid along with it as the electric field is made to travel down the flow path. The effect can be enhanced with the use of small particles in the fluid, which can become charged and move with the field, dragging fluid along with them and thus actuating a pumping effect. If the electric field were made static, i.e., it does not travel along the flow path, then the electric pump might take the form of electrokinetic pumps, such as electro-osmotic pumps. In electro-osmosis, the steady application of an electric field induces fluid within the flow conduit to move because the fluid has a net charge that is counterbalanced by ions that are relatively immobile in a then layer near the conduit wall. The immobility of this thin layer guarantees that the net charge in the bulk fluid will never be equalized, thus providing an opportunity to impel the fluid under the influence of the electric field. Electro-osmosis can be said to actuate a pumping effect.

Alternatively, the pump can be mechanical in nature, wherein the immediate driving force that impels the fluid is mechanical, such as the action of a reciprocating piston or a rotating-vane impeller. The force that drives a mechanical pump can itself be electrical in nature, such as an electric motor, in which case the combination of pump and motor can be described as actuated by electromechanical means.

A further means of fluid flow is magnetic in nature, as in the case of pumping element that moves in response to a changing magnetic field. An example is a piston impeller that moves back and forth with the changing direction of a magnet field. The magnetic field may result from electrical current flowing through a coil. As the current reverses direction, so does the magnetic field and the impeller. Such pumps can be described as magnetically actuated, because the means for actuating the driving element is magnetic.

The present disclosure also includes a method and apparatus for cooling without the use of a pump. In such case, the heat absorbed from the heat exchangers alters the characteristics of the fluid. Such an alteration—a change in density or viscosity—drives the flow of the fluid between the heat exchangers.

The present disclosure exploits some of the properties of a fluid near or above its critical pressure, which enable a reduction in the size of such components as heat exchangers and a pump. These reductions also allow for the process to use less energy. The said fluid is may be carbon dioxide, water, air or a natural hydrocarbon.

Heat transfer can be further improved with the addition of additives to fluid, such as thermally conductive nanoparticles. Such additives improve the heat transfer characteristics of the fluid, such as thermal conductivity. Nanoparticles may also provide a mechanism for inducing fluid flow in EHD devices. In addition, additives can be added to increase the heat capacity of the fluid which helps in reducing the flow rate of the fluid required to cooling certain heat load.

Another way to improve heat transfer is to limit or eliminate lubricants that might be contained in the fluid. Such lubricants would normally leak from the pump or be added to the fluid to increase the mechanical performance of the system. Such lubricants may coat the heat transfer area effectively reducing the heat transfer efficiencies. In a preferred embodiment of this disclosure, the pump—if used at all—is operated without the aid of lubricants and lubricants in the fluid are avoided.

All of the components and interconnections of the apparatus may be connected and sealed into one package. The entire package is contacted with the external surface of a device element and heat is transferred between the device element and the apparatus. In some cases, the components of the cooling apparatus may also be distributed across more than one device element rather than sealed into a single package. For example, a single heat-rejecting heat exchanger might serve all sub-assemblies of an apparatus in a device, not just one of them.

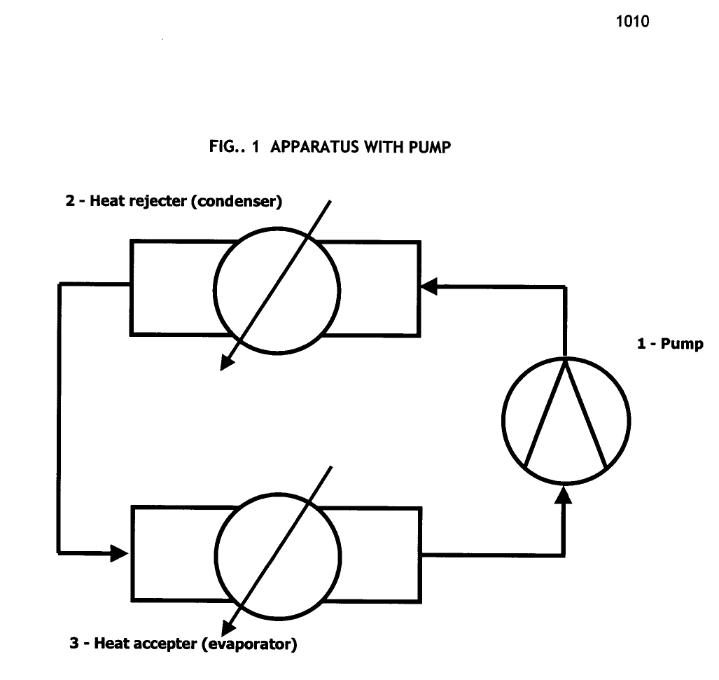

In one preferred embodiment, FIG. 1 shows a schematic of the cycle components of the present disclosure. As detailed and labeled in the diagram, the apparatus is comprised of a pump 1 and heat exchangers for heat rejection (condensing) 2 and heat acceptance (evaporation) 3 in a closed loop with all components connected. Said apparatus has a regulating means and sensors to monitor and control performance and environmental conditions. For example, a sensor can relay temperature information to a control mechanism or software that in turn causes the pump to increase (or decrease) speed so as to vary the rate of fluid flow, and by consequence, the rate of heat dissipated by the apparatus. If the temperature is too high, fluid flow is increased; if the temperature is too low, fluid flow is decreased. Any method of control can be integrated into the cooling device. Power to said apparatus may be derived from the public net of the device or from an independent source. A public net is a circuit contained within the device that derives electric power from a power source that is also contained within the device. It supplies power to all components of the device, hence its description as “public” within the device itself. Such internal power sources typically rectify power that is available from commercial nets. The apparatus as disclosed herein may derive power internally from the public net, or it may be supplied by a separate electrical connection to an independent, commercial net.

The apparatus attaches to the packaging of the integrated circuit and at least one heat exchanger is near or in contact with said device. The heat accepting exchanger 3 of the system faces toward said packaging of the device and is directly in thermal contact with it. Heat exchanger 3 may be located in any position relative to the device, for example above or below the device, and it may have any suitable configuration. The heat rejecting exchanger 2 faces away from said device. Heat exchanger 2 may be located in any position relative to the device and may have any suitable configuration. A fan that is directed toward heat exchanger 2 may be used to discharge heat from the closed loop.

The heat exchanger, or exchangers, used in the apparatus are preferably of a microchannel type, in which case the channel dimensions are less than 1 millimeter in cross-sectional length, width or diameter. The smaller the channel dimension, the larger the wall surface area can be, and hence, the more area there is for heat transfer. Within limits determined by the manufacturability of the channels and the increase in pressure drop, and with it power to drive the pump, channels should be as small as possible.

The heat exchanger may be integrated into the device, typically as part of the device “package,” i.e., components, adhesives and sealants that hold the device together as a single unit. For example, the heat rejector may be mounted atop an integrated circuit, with a fan, and continuously blow heat away from the device package. The heat accepter, meanwhile, by be contained within the device package in the form of a microchannel heat exchanger that is in direct contact with the integrated circuit itself, or more likely, in direct contact with a heat sink that is itself in contact with the integrated circuit.

FIG. 3 shows an array of microchannels within a heat acceptor. The channels are bounded by headers that distribute the fluid coming into the heat exchanger at one end and collect the fluid from the microchannels before discharging the fluid at the other end.

The pump can be selected from commercially available models such as Thar Technologies' P-10, P-50 or P-200 Series pumps, or can be designed to suit the specific cooling application.

In another preferred embodiment, there is a heat exchanger in addition to the one or more heat exchangers within the single unit packaging of the apparatus. Said additional heat exchanger is external to the apparatus but still is connected to the loop of the components within the single apparatus. Piping connects said external heat exchanger to the components within the apparatus packaging, providing a means for fluid flow between components of the cooling apparatus. The external heat exchanger faces away from the device. A fan may be attached to an external heat-rejecting heat exchanger is used to discharge heat from the closed loop.

In electronic devices such as microcomputers, the heat dissipated from an integrated circuit can range from 25 to 1,000 watts, and more typically between 50 and 200 watts. The area available for contact by the heat accepter against such an integrated circuit can rage from between 0.1 square inches and nearly 4.0 square inches. This combination of heat dissipation and area available calls for heat acceptors that are capable of removing as much as 1,000 watts per square inch, but typically in a range of 50 to 300 watts per square inch. The flow rate for a fluid above the critical point that is removing heat at this rate can be measured in milliliters per minute. For carbon dioxide, the rate is between 200 and 1,000 milliliters per minute.

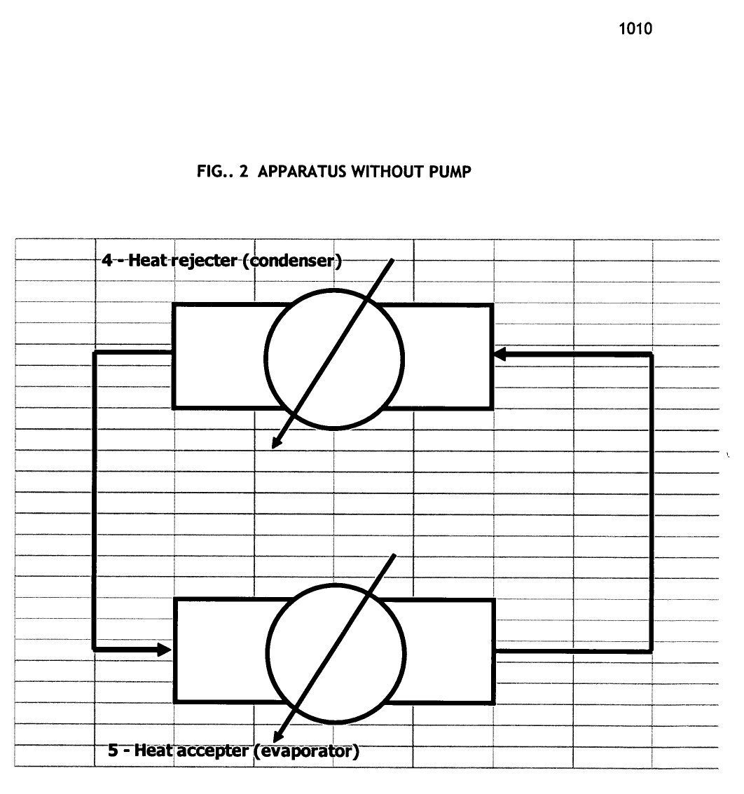

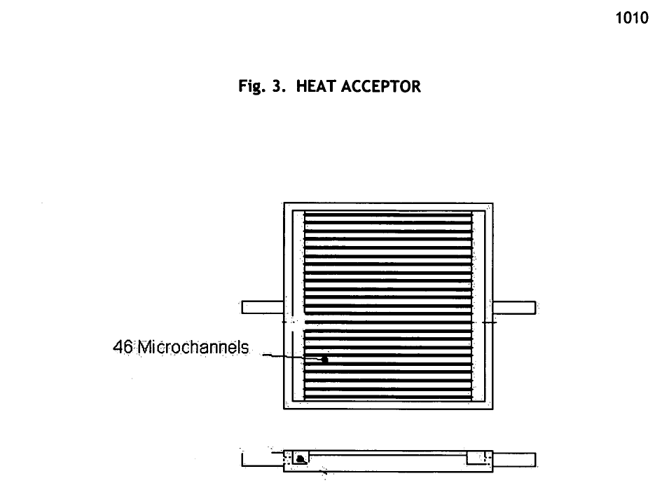

In another preferred embodiment, FIG. 2 shows a schematic of the cycle components of the present disclosure in which case the pump is omitted. As detailed and labeled in FIG. 2, the apparatus is comprised of at least one or more heat exchangers for heat rejection 4 and heat acceptance 5 in a closed, connected loop. Said apparatus has a regulating means and sensors to monitor performance and environmental conditions. In contrast to the pumped apparatus, described above, the sensor output might be used to control the speed of a fan that blows cooling air against the heat rejecter. The temperature difference between components 4 and 5 causes a density gradient that drives fluid flow between them. Low viscosity of the fluid around the critical point also reduces the resistance of the fluid to flow.

The apparatus attaches to the packaging of the integrated circuit and at least one heat exchanger is near or in contact with said packaging. The heat-accepting heat exchanger 5 of the system faces toward said packaging of the device and is directly in contact with it. The heat-rejecting heat exchanger 4 faces away from said packaging. A fan attached to the heat-rejecting heat exchanger 4 is used to discharge heat from the closed loop.

The heat exchanger, or exchangers, used in the apparatus are preferably of a microchannel type, in which case the channel dimensions are less than 1 millimeter in cross-sectional length, width or diameter. The smaller the channel dimension, the larger the wall surface area can be, and hence, the more area there is for heat transfer. Within limits determined by the manufacturability of the channels and the increase in pressure drop, and with it power to drive the pump, channels should be as small as possible.

The heat exchanger may be integrated into the device, typically as part of the device “package,” i.e., components, adhesives and sealants that hold the device together as a single unit. For example, the heat rejector may be mounted atop an integrated circuit, with a fan, and continuously blow heat away from the device package. The heat accepter, meanwhile, by be contained within the device package in the form of a microchannel heat exchanger that is in direct contact with the integrated circuit itself, or more likely, in direct contact with a heat sink that is itself in contact with the integrated circuit.

In another preferred embodiment, there is a heat exchanger in addition to the one or more heat exchangers within the single unit packaging of the apparatus. Said additional heat exchanger is external to the apparatus but still is connected to the loop of the components within the single cooling apparatus. Piping connects said external heat exchanger to the other components within the apparatus, providing a means for fluid flow between said components of the cooling apparatus. The external heat exchanger faces away from the device packaging. A fan attached to the heat-rejecting heat exchanger is used to discharge heat from the closed loop.

There is a plurality of advantages that may be inferred from the present disclosure arising from the various features of the apparatus, systems and methods described herein. It will be noted that other embodiments of each of the apparatuses, systems and methods of the present disclosure may not include all of the features described yet still benefit from at least some of the inferred advantages of such features. Those of ordinary skill in the art may readily devise their own implementations of an apparatus, system and method that incorporate one or more of the features of the present disclosure and fall within the spirit and scope of the disclosure.

### EXAMPLE 1

In the case of carbon dioxide, the fluid would be maintained at a pressure above 1,070 pounds per sq. in. (absolute). Heat capacity is typically between 0.4 and 1.0 Btu per pound-°R, except near the critical point, at which it can jump up to 30 Btu per pound-°R, Thermal conductivity increases by a factor of almost four around the critical temperature. These conditions promote efficient heat acceptance and rejection when heat is exchanged against ambient air. The pressure difference between the heat rejecter and heat accepter is that which corresponds to the pressure drop of the apparatus, and can be as low as a few pounds per square inch. This difference is small enough to be overcome with a small pump.

### EXAMPLE 2

In the case of a pumpless scheme, as shown in FIG. 2, flow is assured by a density gradient, aided by the low viscosity of the fluid near or above the critical point. In the case of carbon dioxide. Density at the critical temperature is 0.63 g/ml at a pressure of 1,100 pounds per sq. inch and drops quickly to half of this density with only a 5° F. temperature rise. Viscosity, meanwhile, remains low, ranging from 0.047 centipoise at the critical temperature to 0.023 centipoise at 93° F., both conditions at 1,100 psi.

I claim:

1. An apparatus for cooling a device comprising:
(a) a fluid near or above its critical pressure;
(b) at least one heat exchanger;
(c) a pump for circulation of the fluid; and
(d) a fluid connection between the heat exchanger and the pump.

2. The apparatus as in claim 1, wherein the device is selected from the group consisting of electrical or electronic components comprising at least an integrated circuit or embedded control.

3. The apparatus as in claim 1, wherein the fluid is selected from the group consisting of carbon dioxide, water, air, and a natural hydrocarbon.

4. The apparatus as in claim 1, wherein the pump utilizes electrical, electromechanical, mechanical or magnetic means of fluid flow.

5. The apparatus as in claim 4, wherein the actuation of the pump is selected from the group consisting of electrohydrodynamic, electroosmotic, magnetic and electromechanical actuations.

6. The apparatus as in claim 1, wherein the at least one heat exchanger is of microchannel type.

7. The apparatus as in claim 1, wherein an absence of lubricants increases performance of the apparatus.

8. The apparatus as in claim 1, further comprising control by software, hardware or other method.

9. The apparatus as in claim 1, further comprising at least one sensor to monitor and control temperature and temperature-related phenomena.

10. The apparatus as in claim 1, wherein power is derived from a public power network of the device.

11. The apparatus as in claim 1, wherein power is derived from an independent source.

12. The apparatus as in claim 1, wherein the at least one heat exchanger and the pump are contained in the apparatus package.

13. The apparatus as in claim 12, further comprising at least one heat exchanger that is external to the apparatus package.

14. The apparatus as in claim 13, wherein the external heat exchanger is connected to the apparatus by a fluidic connection.

15. The apparatus as in any one of claims 12-14, wherein the heat exchanger is integrated into a package of the device.

16. The apparatus as in claim 15, wherein the external heat exchanger is in thermal contact with the device.

17. The apparatus as in claim 1, wherein the fluid comprises thermally conductive nanoparticles to increase cooling performance.

18. The apparatus as in claim 1, further comprising an additional effect selected from the group consisting of electrohydrodynamic, electroosmotic, and magnetic effect to increase cooling performance.

19. An apparatus for cooling a device comprising:
(a) a fluid near or above its critical pressure;
(b) at least two heat exchangers; and
(c) a fluid connection between the heat exchangers.

20. The apparatus as in claim 19, wherein the device is selected from the group consisting of electrical or electronic components comprising at least an integrated circuit or embedded control.

21. The apparatus as in claim 19, wherein the fluid is selected from the group consisting of carbon dioxide, water, air, and a natural hydrocarbon.

22. The apparatus as in claim 19, wherein the at least one heat exchanger is of microchannel type.

23. The apparatus as in claim 19, further comprising a control by software, hardware or other method.

24. The apparatus as in claim 19, further comprising a sensor to monitor and control temperature and temperature-related phenomena.

25. The apparatus as in claim 19, wherein the at least one heat exchanger is contained in the apparatus package.

26. The apparatus as in claim 25, further comprising at least one heat exchanger external to the apparatus package.

27. The apparatus as in claim 26, wherein the external heat exchanger is connected to the apparatus by a fluidic connection.

28. The apparatus as in any one of claims 25-27, wherein the heat exchanger is integrated into the package of the device.

29. The apparatus as in claim 28, wherein the external heat exchanger is in thermal contact with the device.

30. The apparatus as in claim 19, wherein a density difference is maintained between at least two heat exchangers.

31. The apparatus as in claim 19, wherein the fluid comprises thermally conductive nanoparticles to increase cooling performance.

32. The apparatus as in claim 19, further comprising an additional effect selected from the group consisting of electrohydrodynamic, electroosmotic, and magnetic effect to increase cooling performance.

33. A method of cooling a device, the method comprising:
(a) providing a fluid near or above its critical pressure;
(b) transferring heat from the device to the fluid;
(c) transferring heat from the fluid to an external environment; and
(d) providing a pump for fluid flow.

34. The method as in claim 33, wherein the device is selected from the group consisting of electrical or electronic components comprising at least an integrated circuit or embedded control.

35. The method as in claim 33, wherein the fluid is selected from the group consisting of carbon dioxide, water, air, and a natural hydrocarbon.

36. The method as in claim 33, wherein the pump utilizes an electrical, electromechanical, mechanical or magnetic means for fluid flow.

37. The method as in claim 33, wherein the actuation of the pump is selected from the group consisting of electrohydrodynamic, electroosmotic, magnetic and electromechanical actuations.

38. The method as in claim 33, wherein an absence of lubricants increases the performance of the apparatus.

39. The method as in claim 33, further providing a control by software, hardware or other method.

40. The method as in claim 33, further providing at least one sensor to monitor and control temperature and temperature-related phenomena.

41. The method as in claim 33, further providing power from a public power network of the device.

42. The method as in claim 33, further providing power from an independent source.

43. The method as in claim 33, further adding thermally conductive nanoparticles to the fluid to increase cooling performance.

44. The method as in claim 33, further adding an electrohydrodynamic, electroosmotic, or magnetic effect to increase cooling performance.

45. A method for cooling a device comprising
(a) providing a fluid near or above its critical pressure;
(b) transferring heat from the device to the fluid; and
(c) transferring heat from the fluid to an external environment.

46. The method as in claim 45, wherein the device is selected from the group consisting of electrical or electronic components comprising at least an integrated circuit or embedded control.

47. The method as in claim 45, wherein the fluid is selected from the group consisting of carbon dioxide, water, air, and a natural hydrocarbon.

48. The method as in claim 45, further providing a control by software, hardware or other method.

49. The method as in claim 45, further providing at least one sensor to monitor and control temperature and temperature-related phenomena.

50. The method as in claim 45, further providing an addition of thermally conductive nanoparticles to the fluid to increase cooling performance.

51. The method as in claim 45, further providing an addition of an electrohydrodynamic, electroosmotic, or magnetic effect to increase cooling performance.

52. The method as in claim 33 or claim 45 wherein, nanomaterials with high heat capacity are added to the fluid to reduce the fluid flow rate.

53. The apparatus as in claim 1 or claim 19 wherein, nanomaterials with high heat capacity are added to the fluid to reduce the fluid flow rate.

54. The method as in claim 33 or claim 45 wherein the fluid is a high thermal conducting fluid.

55. The apparatus as in claim 1 or claim 19 wherein the fluid is a high thermal conducting fluid.

56. The method as in claim 39 or claim 48 wherein the control software and hardware are integrated with the device.

57. The apparatus as in claim 8 or claim 23 wherein the control software and hardware are integrated with the device.
